(19) United States
(12) Patent Application Publication
(10) Pub. No.: US 2013/0037957 A1
(43) Pub. Date: Feb. 14, 2013

(54) FLUX COMPOSITION, PROCESS FOR PRODUCING ELECTRICALLY CONNECTED STRUCTURES, ELECTRICALLY CONNECTED STRUCTURE, AND SEMICONDUCTOR DEVICE

(71) Applicants: Seiichirou TAKAHASHI, Tokyo (JP); Torahiko YAMAGUCHI, Tokyo (JP); Hirofumi GOTO, Tokyo (JP)

(72) Inventors: Seiichirou TAKAHASHI, Tokyo (JP); Torahiko YAMAGUCHI, Tokyo (JP); Hirofumi GOTO, Tokyo (JP)

(73) Assignee: JSR CORPORATION, Tokyo (JP)

(21) Appl. No.: 13/486,289

(22) Filed: Jun. 1, 2012

(30) Foreign Application Priority Data
Aug. 8, 2011 (JP) 2011-172994
Mar. 19, 2012 (JP) 2012-062305

(51) Int. Cl. B23K 35/363; H01L 23/488; B23K 31/02

(52) U.S. Cl. 257/772; 148/23; 228/214; 257/E23.072

(57) ABSTRACT

A flux composition includes an alditol (A) and a polymer (B) which has a repeating structural unit represented by Formula (1):

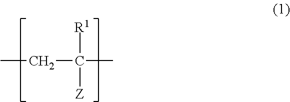

(wherein R¹ is a hydrogen atom or a methyl group, and Z is a hydroxyl group, an oxo group, a carboxyl group, a formyl group, an amino group, a nitro group, a mercapto group, a sulfo group, an oxazoline group, an imide group, a group having an amide structure, or a group having any of these groups).

The flux composition allows substrates with bumps such as pillar bumps to be electrically connected to each other by reflowing of such bumps without causing any exposure of the bumps from the flux during reflowing, thus resulting in a satisfactory electrically connected structure.

### BACKGROUND OF THE INVENTION

1. Technical Field

The present invention relates to a flux composition, a process for producing electrically connected structures, an electrically connected structure and a semiconductor device.

2. Related Art

A flux composition has been used when components such as electronic parts are to be electrically connected to a component-mounting substrate. Because fusible conductive members such as solders are heated to 200° C. to 300° C. when they are thermally fused (reflowed), conductive members of electronic parts such as solders and copper foils are easily oxidized to form an oxide film unless any flux composition is used, thus failing to establish a good electrical connection. A flux composition covers conductive members of electronic parts such as solders and copper foils so as to block oxygen and to prevent these conductive members of electronic parts such as solders and copper foils from being oxidized. In addition, a flux composition reduces oxides that have been already formed, and also allows a fused solder to exhibit good wetting properties, thereby allowing components such as electronic parts to have a good electrical connection.

For example, Patent Literature 1 discloses a flux composition that includes a component such as KAlF₄ having an effect of removing Mg components, as well as a water soluble organic resin such as polyvinyl alcohol, a thickening agent and water. Patent Literature 2 discloses a flux composition that includes an acetylated EO.PO block polymer and a polyglycerol.

### CITATION LIST

### Patent Literatures

Patent Literature 1: JP-A-2009-220174

Patent Literature 2: JP-A-2004-158728

### SUMMARY OF INVENTION

When components such as electronic parts having pillar-shaped fusible conductive members (pillar bumps) are electrically connected, the conductive members are exposed from a flux composition during reflowing due to their shape and the attachment of the flux composition becomes nonuniform, possibly failing to form a satisfactory electrically connected structure.

In the case of pillar bumps which contain two different kinds of metals such as those described in JP-A-2006-332694, the fact that wettability differs depending on the types of metals makes it more likely for the conductive members to be exposed during reflowing and for the flux composition to be attached nonuniformly, possibly resulting in a failure to form a satisfactory electrically connected structure.

It is an object of the present invention to provide a flux composition that allows substrates having bumps such as pillar bumps to be electrically connected to each other by reflowing of such bumps without causing any exposure of the bumps from the flux during reflowing, thus allowing for the production of satisfactory electrically connected structures.

The present invention achieves the above object by providing the following.

[1] A flux composition that includes an alditol (A) and a polymer (B) which has a repeating structural unit represented by Formula (1):

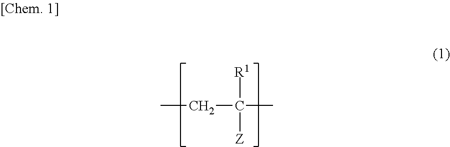

(wherein R¹ is a hydrogen atom or a methyl group, and Z is a hydroxyl group, an oxo group, a carboxyl group, a formyl group, an amino group, a nitro group, a mercapto group, a sulfo group, an oxazoline group, an imide group, a group having an amide structure, or a group having any of these groups).

[2] The flux composition described in [1], wherein Z in Formula (1) is a group having an amide structure.

[3] The flux composition described in [1] or [2], wherein the content of the polymer (B) is 10 to 200 parts by mass with respect to 100 parts by mass of the alditol (A).

[4] The flux composition described in [1] or [2], wherein the alditol (A) and the polymer (B) are soluble in water.

[5] A process for producing electrically connected structures, including reflowing a fusible conductive portion using the flux composition described in [1] or [2].

[6] An electrically connected structure produced by the process for producing electrically connected structures described in [5].

[7] A semiconductor device that includes the electrically connected structure described in [6].

The flux composition according to the present invention allows substrates with bumps such as pillar bumps to be electrically connected to each other by reflowing of such bumps without causing any exposure of the bumps from the flux during reflowing, thus allowing for the production of a satisfactory electrically connected structure.

### BRIEF DESCRIPTION OF THE DRAWINGS

FIG. 1 is a chart that shows the temperature conditions of reflowing performed in EXAMPLE 1.

FIGS. 2A to 2C illustrate shapes of solder sections of pillar bumps provided on a silicon wafer that occur after the pillar bumps are reflowed and a flux is washed away with pure water.

FIGS. 3A to 3C are schematic views illustrating an example of the process for producing electrically connected structures according to the present invention.

### DESCRIPTION OF EMBODIMENTS

### 1. Flux Composition

A flux composition is a fusing agent that is used in combination with a brazing material such as a solder or a low melting metal in the production of electrically connected structures, in particular in joining of metal members, in atmospheric pressure in the presence of oxygen. Such a flux composition is used for the purposes of removing foreign matters such as oxides present on joint surfaces, increasing the spreadability of a brazing material by lowering the interfacial tension of members to be joined together with respect to the brazing material, and preventing the oxidation of metals of joint surfaces.

A flux composition according to the present invention includes an alditol (A) and a polymer (B) which has a repeating structural unit represented by Formula (1):

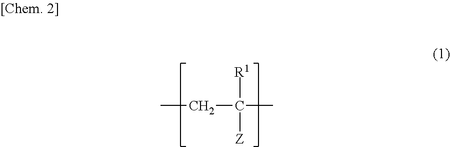

(wherein R¹ is a hydrogen atom or a methyl group, and Z is a hydroxyl group, an oxo group, a carboxyl group, a formyl group, an amino group, a nitro group, a mercapto group, a sulfo group, an oxazoline group, an imide group, a group having an amide structure, or a group having any of these groups).

### 1-1. Alditol (A)

The alditol (A) is an active species in the flux composition according to the invention. The alditol has a reduction effect and prevents the oxidation of solders and joined members during soldering.

The alditols (A) are not particularly limited as long as they have an effect of preventing solders and other materials from being oxidized. Examples thereof include sugar alcohols such as glycerol, erythritol, threitol, ribitol, arabinitol, xylitol, allitol, sorbitol, mannitol, iditol, galactitol and talitol.

Of these, glycerol is particularly preferable because glycerol has high reducing power and can efficiently prevent the oxidation of materials such as solders.

It is preferable that the alditol (A), as well as a polymer (B) described later, be soluble in water. When the alditol (A) and the polymer (B) are both water soluble, the inventive flux composition exhibits water solubility so as to make it possible that substrates which have been soldered using the inventive flux composition are cleaned of flux residues by being washed with water instead of an organic solvent. Such a water soluble flux composition can be handled easily and achieves higher environmental friendliness. As used herein, the term “water soluble” means that the solubility in water at 25° C. and 1 bar is not less than 0.1 S. All the compounds described above as examples of the alditols (A) such as glycerol are water soluble.

### 1-2. Polymer (B)

The polymer (B) has a repeating structural unit represented by Formula (1) above.

The inventive flux composition contains the alditol (A), which is an active species, and the polymer (B) in combination. With this configuration, the flux composition allows bumped substrates to be electrically connected to each other by reflowing of the bumps while effectively preventing the bumps from being exposed from the flux during reflowing. The reason why this advantageous effect is obtained is probably because the combination of the alditol (A) and the polymer (B) suppresses a decrease in the viscosity of the flux composition at a high temperature such as a temperature at which reflowing is carried out.

In Formula (1), R¹ is a hydrogen atom or a methyl group. The letter Z indicates a functional group having a dipole moment and capable of forming a hydrogen bond. Specific examples of the functional groups Z include a hydroxyl group, an oxo group, a carboxyl group, a formyl group, an amino group, a nitro group, a mercapto group, a sulfo group, an oxazoline group, an imide group, a group having an amide structure, and a group having any of these groups. The polymer (B) may contain a single kind of the functional group Z, or two or more kinds of the functional groups Z.

Specific examples of the polymers (B) include polyvinylpyrrolidone, polyvinyl alcohol (including partially saponified products), polyacrylic acid, polymethacrylic acid, poly(2-hydroxyethyl acrylate), poly(2-hydroxyethyl methacrylate), poly(4-hydroxybutyl acrylate), poly(4-hydroxybutyl methacrylate), poly(glycosyloxyethyl acrylate), poly(glycosyloxyethyl methacrylate), polyvinyl methyl ether, polyvinyl acetal (including partially acetalized products), polyethyleneimine, styrene-maleic anhydride copolymer, polyvinylamine, polyallylamine and EPOCROS (product name, manufactured by NIPPON SHOKUBAI CO., LTD.).

The functional group Z is preferably a group having an amide structure. When the functional group Z is a group having an amide structure, the flux composition can prevent more reliably the exposure of bumps from the flux during reflowing when bumped substrates are electrically connected to each other by reflowing of such bumps using the flux composition. Polyvinylpyrrolidone is an example of the polymer (B) in which the functional group Z is a group having an amide structure.

The molecular weight (Mw) of the polymer (B) is usually 1,000 to 1,000,000. This molecular weight is weight average molecular weight measured by gel permeation chromatography relative to polystyrenes.

In the flux composition of the invention, the content of the polymer (B) is preferably 10 to 200 parts by mass, more preferably 20 to 130 parts by mass, and still more preferably 50 to 120 parts by mass with respect to 100 parts by mass of the alditol (A). This content of the polymer (B) ensures that the flux composition prevents more reliably the exposure of bumps from the flux composition during reflowing when bumped substrates are electrically connected to each other by reflowing of such bumps using the flux composition.

It is preferable that the polymer (B) as well as the alditol (A) described above be soluble in water. When the polymer (B) and the alditol (A) are both water soluble, the inventive flux composition exhibits water solubility so as to make it possible that substrates which have been soldered using the inventive flux composition are cleaned of flux residues by being washed with water instead of an organic solvent. Such a water soluble flux composition can be handled easily and achieves higher environmental friendliness. As used herein, the term “water soluble” means that the solubility in water at 25° C. and 1 bar is not less than 0.1 S. All the polymers described above as examples of the polymers (B) such as polyvinylpyrrolidone are water soluble.

### 1-3. Other Components

The flux composition according to the invention may contain other components while still achieving the advantageous effects of the invention. Examples of such additional components include solvents, activating agents and thixotropic agents.

Solvents may be used in order to control the viscosity of the flux composition as well as to control the interfacial tension of the flux composition with respect to materials. For example, solvents described in JP-A-2010-179360 may be used. Specific examples include water; water-soluble solvents such as isopropanol, butanol, ethylene glycol, diethylene glycol, triethylene glycol, tetraethylene glycol, polyethylene glycol, propylene glycol, dipropylene glycol, tripropylene glycol, butanediol, pentanediol, hexanediol, fatty acid esters of diglycerols such as diglycerol caprylate, polyoxyethylene polyglycerol ether and polyoxypropylene polyglycerol ether; and water-insoluble solvents such as ethylene glycol monoalkyl ether acetates, propylene glycol monoalkyl ethers, propylene glycol dialkyl ethers, propylene glycol monoalkyl ether acetates, carbitol, lactates, aliphatic carboxylates and aromatic hydrocarbons.

Of these, solvents that can be volatilized easily are preferable. In more detail, solvents that boil at a reflowing temperature or below, usually with a boiling temperature of not more than 260° C. at atmospheric pressure, are preferable. In the case where the alditol (A) and the polymer (B) are water soluble, a water soluble solvent is preferable in view of miscibility with these components. A single, or two or more kinds of solvents may be used.

Activating agents may be used in order to increase the reduction ability of the flux composition. Examples of the activating agents include those described in JP-A-2010-179360.

Thixotropic agents may be used in order to give thixotropic properties to the flux composition. Examples of the thixotropic agents include those described in JP-A-2010-179360.

### 2. Process for Producing Electrically Connected Structures

A process for producing electrically connected structures according to the present invention includes reflowing a fusible conductive portion using the inventive flux composition described above, thus establishing an electrical connection. The flux composition of the invention can reliably prevent the oxidation of fusible conductive portions during reflowing, thereby allowing for the production of satisfactory electrically connected structures.

In an exemplary embodiment, the inventive process for producing electrically connected structures includes the following steps.

Step 1: The inventive flux composition is applied to a substrate that is provided with fusible conductive portions capable of establishing an electrical connection, thereby covering the fusible conductive portions with the flux composition.

Step 2: The substrate and another substrate that is provided with conductive portions capable of establishing an electrical connection are arranged such that the fusible conductive portions provided on the substrate and the conductive portions provided on the other substrate are in an opposing relation with the flux composition interposed between the substrates.

Step 3: The fusible conductive portions on the substrate are reflowed by a heat treatment so as to join each pair of the conductive portions opposing each other, thereby electrically connecting the substrate and the other substrate.

### 2-1. Step 1

The step 1 is schematically illustrated in FIG. 3A. In the step 1, an inventive flux composition 13 is applied to a substrate 12 that is provided with fusible conductive portions 11 capable of establishing an electrical connection, thereby covering the fusible conductive portions 11 with the flux composition 13.

The fusible conductive portions 11 may be, for example, bumps. The fusible conductive portions 11 may be formed of a solder material alone or may be pillar bumps that have a pillar section which is in connection with a plate section of the substrate 12 and is formed of a material other than solder materials such as Cu, Ni, Au, Ag, Al or Zn, and a solder section which is formed at the end of the pillar section and is made of a solder material.

Examples of the solder materials include lead-containing alloys such as Sn—Pb alloys, Sn—Pb—Ag alloys, Sn—Pb—Bi alloys, Sn—Pb—In alloys and Sn—Pb—Sb alloys, and lead-free alloys such as Sn—Sb alloys, Sn—Bi alloys, Sn—Ag alloys and Sn—Zn alloys. These alloys may contain other elements such as Ag, Cu, Bi, In, Ni and P.

For example, the substrate 12 may be a substrate which has wires (not shown) electrically connected to the fusible conductive portions 11 and an insulating layer (not shown). For example, the insulating layer may be a layer that contains an organic component as the main component. Specific examples of the insulating layers include resin layers described in literature such as Japanese Patent No. 3812654, JP-A-2007-314695, JP-A-2008-107458, JP-A-2006-189788, WO 2009/072492 and JP-A-2001-033965.

Examples of the insulating layers further include base materials such as semiconductor wafers, glass plates and resin plates. That is, the substrate may be any of various substrates such as component-mounting substrates and chip-mounting substrates and various electronic parts such as electronic circuit modules, flip chip ICs and semiconductor chips.

The flux composition 13 may be applied to the substrate 12 by, for example, spin coating, knife coating, roll coating, doctor blade coating, curtain coating, die coating, wire coating, screen printing with a screen printer, or inkjet coating.

After the flux composition 13 is applied, a heat treatment may be carried out as required in order to enhance the temporal fixing performance with respect to a substrate 21 by volatilizing the solvent and other volatile components contained in the flux composition 13 so as to increase the viscosity, as well as in order to increase the reduction ability of the flux composition 13.

### 2-2. Step 2

The step 2 is schematically illustrated in FIG. 3B. In the step 2, the substrate 12 and another substrate 21 that is provided with conductive portions 22 capable of establishing an electrical connection are arranged such that the fusible conductive portions 11 provided on the substrate 12 and the conductive portions 22 provided on the substrate 21 are in an opposing relation with the flux composition 13 interposed between the substrates. As illustrated in FIG. 3B, the substrate 12 and the substrate 21 are arranged so as to place the opposing fusible conductive portions 11 and conductive portions 22 in contact with each other.

For example, the substrate 21 may be a substrate which has wires (not shown) electrically connected to the conductive portions 22 capable of establishing an electrical connection and an insulating layer (not shown). Similarly to the fusible conductive portions 11, the conductive portions 22 may be fusible. Similarly to the insulating layer of the substrate 12, the insulating layer of the substrate 21 may be a layer that contains an organic component as the main component, a semiconductor wafer, a glass plate, a resin plate or the like.

After the substrate 12 and the substrate 21 are arranged with the above configuration, the viscosity of the flux composition 13 may be controlled so as to prevent the substrates 12 and 21 from moving out of alignment. That is, the flux composition 13 may be used as a temporal fixing material that prevents the substrates 12 and 21 from being misaligned relative to each other during reflowing in the step 3.

### 2-3. Step 3

The step 3 is schematically illustrated in FIG. 3C. In the step 3, the fusible conductive portions 11 are reflowed by a heat treatment so as to join each pair of the fusible conductive portions 11 and the conductive portions 22 opposing each other, thereby electrically connecting the substrate 12 and the substrate 21.

The heating temperature in the reflowing may be determined appropriately in accordance with the melting temperature of the fusible conductive portions 11 and the type of the inventive flux composition 13. The heating temperature is usually 80 to 300° C., and preferably 100 to 270° C.

By reflowing, the fusible conductive portions 11 and the conductive portions 22 opposing each other are joined together, thus forming conductive connection portions 31. Through the step 3, the substrate 12 and the substrate 21 are electrically connected to each other via the conductive connection portions 31.

In the case where there are flux residues after reflowing, the structure may be washed with a solvent in order to remove such flux residues. Examples of the solvents for use in washing include the solvents described in “1-3. Other components”. In particular, flux residues can be removed by washing with water when the alditol (A) and the polymer (B) are both water soluble.

Thus, such a water soluble flux composition can be handled easily and achieves higher environmental friendliness.

### 3. Electrically Connected Structure

An electrically connected structure according to the present invention is produced by the above process for producing electrically connected structures. Because of the use of the flux composition in the production of the electrically connected structure, the electrically connected structure is free from oxidation at, for example, the fusible conductive portions 11 and the conductive portions 22 in FIG. 3. Thus, the electrically connected structure of the invention achieves an excellent electrical connection. The electrically connected structure may be used in various devices such as semiconductor devices.

### 4. Semiconductor Device

The use of the inventive flux composition allows for the manufacturing of semiconductor devices that have the aforementioned electrically connected structure as well as components such as semiconductor elements, semiconductor packages, solid-state image sensors and optical semiconductor elements.

### EXAMPLES

The present invention will be described in detail by presenting examples hereinbelow without limiting the scope of the invention. The term “parts” in examples is on the mass basis.

### [1] Preparation of Flux Compositions

### Examples 1 to 20 and Comparative Example 1

The components described in Table 1 below were mixed in the proportions shown in Table 1 to give flux compositions representing EXAMPLES 1 to 20 and COMPARATIVE EXAMPLE 1. The numbers described in Table 1 indicate parts by mass. The details of the components are described below. The term “Mw” is a weight average molecular weight measured by gel permeation chromatography relative to polystyrenes. The viscosity was measured with a Brookfield type viscometer at 23° C.

A-1: glycerol

B-1: polyvinylpyrrolidone (Mw: 6000 to 15000, polymerization degree: 60 to 930)

B-2: polyvinyl alcohol (saponification degree: 87 to 89 mol %, polymerization degree: 300 to 500)

C-1: polyethylene glycol (viscosity: 0.003 to 0.02 Pa·s)

C-2: tetraethylene glycol

C-3: polyoxypropylene polyglycerol ether (viscosity: 0.3 to 0.5 Pa·s)

C-4: diglycerol caprylate (viscosity: 0.3 to 0.5 Pa·s)

C-5: polyoxyethylene polyglycerol ether (viscosity: 0.3 to 0.5 Pa·s) 22

TABLE 1

| | | | | | | | | | Washing | |
|---|---|---|---|---|---|---|---|---|---|---|
| | A-1 | B-1 | B-2 | C-1 | C-2 | C-3 | C-4 | C-5 | properties | Solder shape |
| EX. 1 | 100 | 100 | — | — | 80 | — | — | — | A | A |
| EX. 2 | 100 | 100 | — | 60 | 80 | — | — | — | A | A |
| EX. 3 | 100 | 150 | — | — | 80 | — | — | — | A | B |
| EX. 4 | 100 | 100 | — | — | 1400 | — | 60 | — | A | A |
| EX. 5 | 100 | 100 | — | — | 3800 | — | 60 | — | A | A |
| EX. 6 | 100 | 100 | — | — | 600 | 60 | — | — | A | A |
| EX. 7 | 100 | 100 | — | — | 1400 | 60 | — | — | A | A |
| EX. 8 | 100 | 100 | — | — | 3800 | 60 | — | — | A | A |
| EX. 9 | 100 | — | 100 | — | 1400 | 60 | — | — | A | A |
| EX. 10 | 100 | — | 100 | — | 3800 | 60 | — | — | A | A |
| EX. 11 | 100 | 100 | — | — | 600 | — | — | 60 | A | A |
| EX. 12 | 100 | 100 | — | — | 1400 | — | — | 60 | A | A |
| EX. 13 | 100 | 100 | — | — | 3800 | — | — | 60 | A | A |
| EX. 14 | 100 | 100 | — | — | 600 | — | 60 | — | A | A |
| EX. 15 | 100 | 50 | — | — | 80 | — | — | — | A | A |
| EX. 16 | 100 | 100 | — | 60 | 3800 | — | — | — | A | A |
| EX. 17 | 100 | 100 | — | — | 3800 | — | 60 | — | A | A |
| EX. 18 | 100 | 100 | — | — | 3800 | 60 | — | — | A | A |
| EX. 19 | 100 | — | 100 | — | 3800 | 60 | — | — | A | A |
| EX. 20 | 100 | 100 | — | — | 3800 | — | — | 60 | A | A |
| COMP. EX. 1 | 100 | — | — | 60 | 80 | — | — | — | A | C |

### [2] Evaluation of Flux Compositions

The flux compositions of EXAMPLES 1 to 20 and COMPARATIVE EXAMPLE 1 were evaluated in the following manner. The results are described in Table 1.

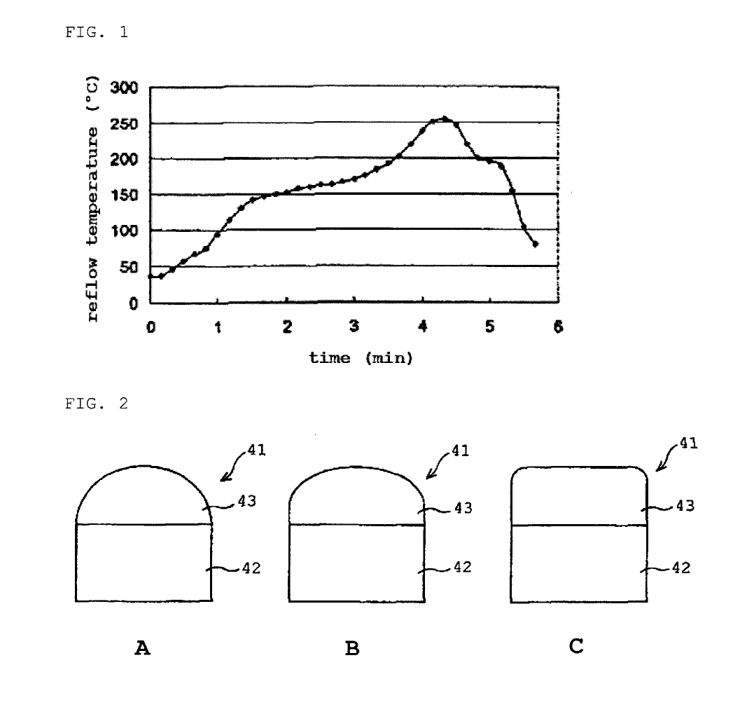

The flux compositions of EXAMPLES 1 to 15 and COMPARATIVE EXAMPLE 1 were each applied by a spin coating method onto a silicon wafer with a diameter of 4 inches provided with a plurality of pillar bumps, thus covering the pillar bumps with the flux composition. Separately, the flux compositions of EXAMPLES 16 to 20 were each applied by an inkjet method onto a silicon wafer with a diameter of 4 inches provided with a plurality of pillar bumps, thus covering the pillar bumps with the flux composition. Each of the pillar bumps was 100 μm in length, 100 μm in width and 100 μm in height. The lower half on the silicon wafer side was a pillar section formed of copper, and the upper half was a solder section formed of a Sn—Ag alloy. The solder was reflowed under the temperature conditions shown in FIG. 1, and thereafter the silicon wafer was washed with pure water.

Whether flux residues had been removed by washing with pure water was examined by observing the washed silicon wafer with an electron microscope. The “washing properties” were evaluated on the basis of the following criteria.

### Washing Properties

A: There were no flux residues.

C: Flux residues remained.

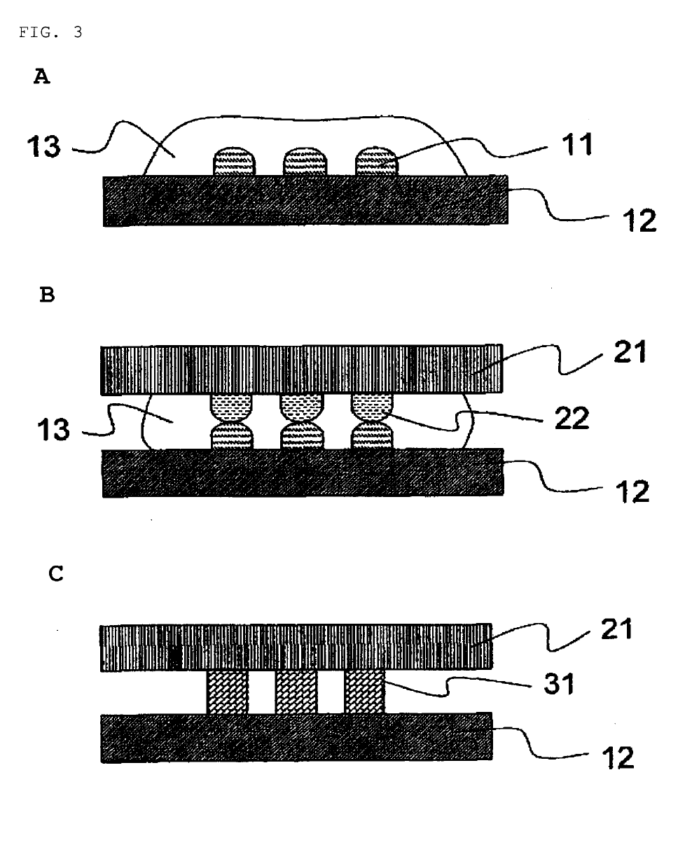

Separately, the shape of the solder section of the washed pillar bump was observed with an electron microscope in order to examine whether the pillar bump had been covered with the flux composition during reflowing without being exposed from the flux composition. The “solder shape” was evaluated with reference to FIGS. 2A to 2C and on the basis of the criteria described below.

FIGS. 2A to 2C illustrate post-reflowing shapes of the pillar bumps 41 provided on the silicon wafers used in EXAMPLES 1 to 20 and COMPARATIVE EXAMPLE 1, viewed in parallel with the silicon wafer and in parallel with a side surface of the pillar bump 41. The pillar bump 41 has a pillar section 42 and a solder section 43. The solder section 43 of the pillar bump 41 is oxidized more heavily as a larger area of the pillar bump 41 is exposed from the flux composition during reflowing, thus resulting in a great change in the shape of the solder section 43. Thus, the degree of the exposure of the pillar bump 41 from the flux composition during reflowing can be evaluated based on the shape of the solder section 43 after washing.

FIG. 2A shows a shape of the solder section 43 that has not been oxidized, namely, a shape of the solder section 43 that occurs when the pillar bump 41 has not been exposed from the flux composition during reflowing. FIG. 2B shows a shape of the solder section 43 that has been slightly oxidized, namely, a shape of the solder section 43 that occurs when the pillar bump 41 has been exposed from the flux composition during reflowing but the exposed area is small. FIG. 2C shows a shape of the solder section 43 that has been strongly oxidized, namely, a shape of the solder section 43 that occurs when the pillar bump 41 has been exposed from the flux composition during reflowing and the exposed area is large. As illustrated, the shape of the solder section 43 becomes closer to a hemispheric shape with decreasing degree of oxidation, and becomes closer to a cubic shape with increasing degree of oxidation.

### Solder Shape

A: The solder sections 43 had a shape illustrated in FIG. 2A.

B: The solder sections 43 had a shape illustrated in FIG. 2B.

C: The solder sections 43 had a shape illustrated in FIG. 2C.

### REFERENCE SIGNS LIST

11 fusible conductive portion
12 substrate
13 flux composition
21 substrate
22 conductive portion
31 conductive connection portion
41 pillar bump
42 pillar section
43 solder section

What is claimed is:

1. A flux composition that comprises an alditol (A) and a polymer (B) which has a repeating structural unit represented by Formula (1): 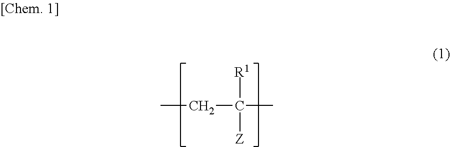
(wherein R¹ is a hydrogen atom or a methyl group, and Z is a hydroxyl group, an oxo group, a carboxyl group, a formyl group, an amino group, a nitro group, a mercapto group, a sulfo group, an oxazoline group, an imide group, a group having an amide structure, or a group having any of these groups).

2. The flux composition according to claim 1, wherein Z in Formula (1) is a group having an amide structure.

3. The flux composition according to claim 1 or 2, wherein the content of the polymer (B) is 10 to 200 parts by mass with respect to 100 parts by mass of the alditol (A).

4. The flux composition according to claim 1 or 2, wherein the alditol (A) and the polymer (B) are soluble in water.

5. A process for producing electrically connected structures, comprising reflowing a fusible conductive portion using the flux composition described in claim 1 or 2.

6. An electrically connected structure produced by the process for producing electrically connected structures described in claim 5.

7. A semiconductor device that comprises the electrically connected structure described in claim 6.
